(19) United States
(12) Patent Application Publication
(10) Pub. No.: US 2025/0291145 A1
(43) Pub. Date: Sep. 18, 2025

(54) OPTICAL INTERCONNECTION MODULES FOR AI NETWORKS

(71) Applicant: Panduit Corp., Tinley Park, IL (US)

(72) Inventors: Brian L. Kelly, Oak Forest, IL (US); Kevin A. Marley, Joliet, IL (US); Robert A. Reid, Battle Ground, IN (US); Jose M. Castro, Naperville, IL (US); Thomas M. Sedor, Orland Park, IL (US); Gregory L. Kuffel, Plainfield, IL (US); Robert R. Wagner, Naperville, IL (US); Shawn T. Kemp, Crete, IL (US)

(73) Assignee: Panduit Corp., Tinley Park, IL (US)

(21) Appl. No.: 19/059,581

(22) Filed: Feb. 21, 2025

Related U.S. Application Data
(60) Provisional application No. 63/564,583, filed on Mar. 13, 2024.

(51) Int. Cl. G02B 6/44; G02B 6/38; H05K 7/14

(52) U.S. Cl. CPC G02B 6/44524; G02B 6/3895; H05K 7/1491

(57) ABSTRACT

An application-specified adapter-aligned enclosure to be placed in a server cabinet has a hole in at least one of a top or bottom of the enclosure. A plurality of fiber optic connectors are distributed on a front face of the enclosure such that the connectors are arranged in a plurality of groups which are vertically arranged in a specific manner related to at least one of a rack unit of a cabinet or an equipment port interval.

### CROSS REFERENCE TO RELATED APPLICATION(S)

This application claims benefit to U.S. Provisional Patent Application No. 63/564,583, filed Mar. 13, 2024, the entirety of which is hereby incorporated by reference herein.

### FIELD OF INVENTION

The present disclosure relates generally to enclosures for fiber optic connections and more specifically to an enclosure that has fiber optic connections grouped at intervals related to a cabinet's Rack Unit, equipment port interval, or some other specified alignment.

### BACKGROUND

Data centers are made up of white space. This is usable floor space that is highly conditioned and controlled for humidity, temperature, and dust. Cabinets provide the racking that servers, switches, and other equipment is placed into to make the data center operate. The spaces within these cabinets are called Rack Units (RU). A RU of space is 1.75″×19″ in a horizontal orientation (FIG. 1).

Data center white space is a valuable commodity. Data center operators use every RU of space that they can to maximize the utilization of the data center space. When RU within a cabinet is exhausted, a data center operator must install another cabinet or revert to alternative methods of racking equipment such as installing additional space for non-cooling items, such as patch panels, above the cabinet, which are often not a suitable solution for most applications.

Future datacenters will require not only optimization of the white space but also high bandwidth power-efficient networks to connect servers to accommodate for highly distributed computing, machine learning (ML) high levels of virtualization, and data replication among other functions. Datacenter network architecture design is critical to ensure that targeted deployment cost and performance of the datacenter are achieved. Networking architecture should enable flexible and scalable networks. Common network designs include the top of the rack (ToR), middle of the row (MoR), and EoR (End of the Row) configurations. In ToR, the switch, inside the rack, connects to the servers using passive or active Direct Attach Cable (DAC) at 100 Gbps or higher data rates. Using fiber for those short reaches becomes unnecessary. Until today, ToR architecture where switches are located on the top of the server rack, is cost-effective and therefore more popular than EoR or MoR.

However, advances in the Application Specific Integrated Circuits (ASIC) used in the switches have recently increased significantly the high-speed ports of a switch, e.g., 256 50G ports. For equivalent data rates, those high-radix switches, located in the MoR or EoR, can serve all the servers in a row, consuming significantly less power per port than smaller ToR switches. Therefore, EoR/MoR architectures today are becoming more efficient than ToR. As switch technology continues to evolve this trend is likely to continue.

To adopt these power-efficient technologies, high radix switches populated with transceivers capable of operating in break mode can be used. FIG. 2 illustrates the case, where a high radix switch, with 400GBASE-SR4 modules, located at the MoR, uses patch panels located at the top of the rack, to connect to all servers in a row.

However, using a traditional patch panel as shown in the figure, occupies valuable white space in the data center reducing space for revenue-generating servers or storage. Moreover, the dissimilar connection lengths between the patch panel and servers, as shown in the figure, can impact the cleanliness and maintenance of the cabling installation. As the size of the data center grows it is expected failure of components such as optical transceivers requires easy identification of the optical interconnection for fast replacement.

To optimize the use of white space, while deploying architectures for high-bandwidth energy-efficient optical networks, it will be desirable to minimize the RU space used by the patch panel shown in FIG. 2, and provide simple connection paths, simple to visualize and maintain.

### SUMMARY

An application-specified adapter-aligned enclosure to be placed in a server cabinet has a hole in at least one of a top or bottom of the enclosure. A plurality of fiber optic connectors are distributed on a front face of the enclosure such that the connectors are arranged in a plurality of groups which are vertically arranged in a specific manner related to at least one of a rack unit of a cabinet or an equipment port interval.

### BRIEF DESCRIPTION OF THE DRAWINGS

FIG. 1 shows one Rack Unit (RU) space of a cabinet.

FIG. 2 shows a middle of the row (MoR) architecture with a high radix switch.

FIG. 3 shows a partial trimetric view of the present invention.

FIG. 4 shows a front view of the present invention.

FIG. 5A shows a grommet that can be used with the present invention to connect larger multi-fiber whips.

FIG. 5B shows a grouping of fiber adapters that can be used with the present invention.

FIG. 6 shows a front view of a server cabinet using the present invention.

FIG. 7 shows a rear trimetric view of the present invention highlighting its attachment structures.

FIG. 8 shows a trimetric view of the present invention attached to a PDU.

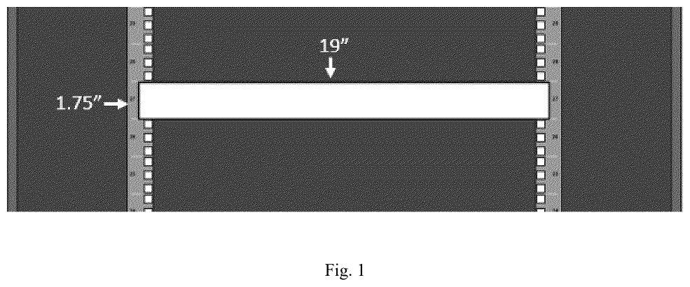

### DESCRIPTION OF INVENTION

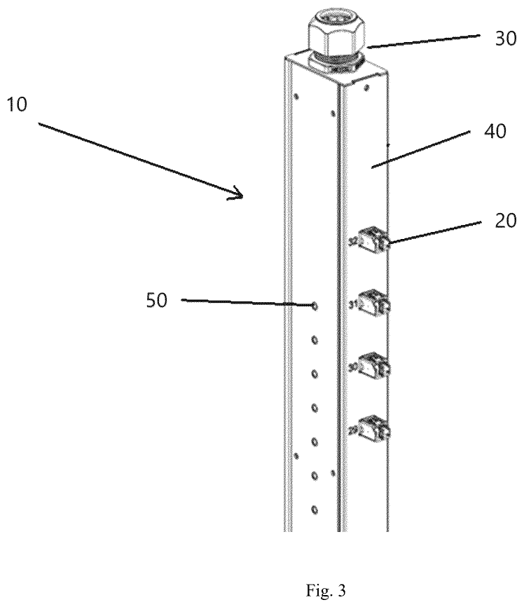

The concept is a generally rectangular enclosure 10 made of metal or plastic with fiber adapters 20 located across the front panel, a hole 30 at the top (or bottom) panel for accepting a modular plate 40 which houses fiber cable or fiber optic adapters and mounting features 50 across the rear and side panels for securing the enclosure to a surface (FIG. 3). The fiber adapters 20 (or groups of fiber adapters) are spaced at intervals in an application-specified aligned arrangement. These application-specified adapter-aligned arrangements include but are not limited to: 1RU intervals, equipment port aligned intervals, or at any specified interval, per application need.

The disclosed device is an application-specified adapter-aligned enclosure enabling simple mapping of optical ports from EOR or MOR switch to server ports, using shorter patching cabling of uniform size. This simplifies the deployment and maintenance of the network, allowing simple identification of the ports and replacement of optical transceivers when needed. The cleaner organization of the cables in the rack enables the use of faster mapping and documentation of the networks using QR or bar codes placed on the side top or bottom of the adapters.

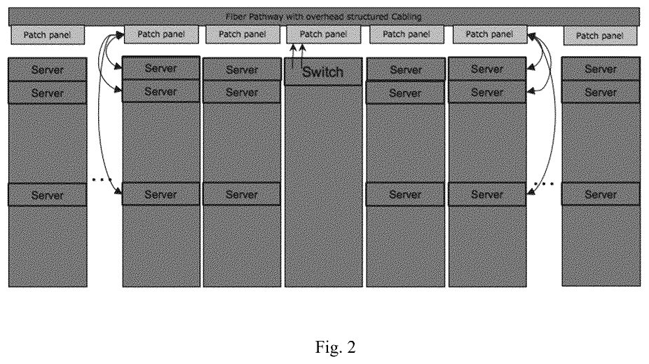

In one embodiment, the enclosure can be placed in the rear of a server cabinet to provide fiber breakout network connectivity to a server from a remote switch in an End of Row (EoR) or Middle of Row (MoR) (FIG. 2) architecture. Alternatively, it could be attached to the back rail, cable management finger slots, a PDU in the rear of the cabinet, or another attachment slot. The enclosure could run nearly the height of the cabinet to provide connectivity to all the RU within the cabinet.

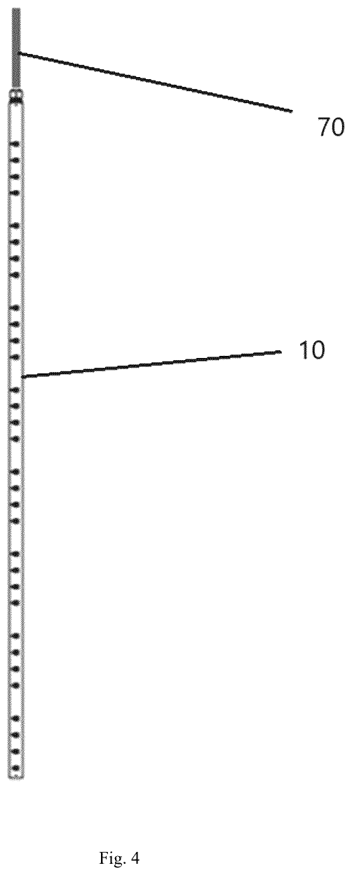

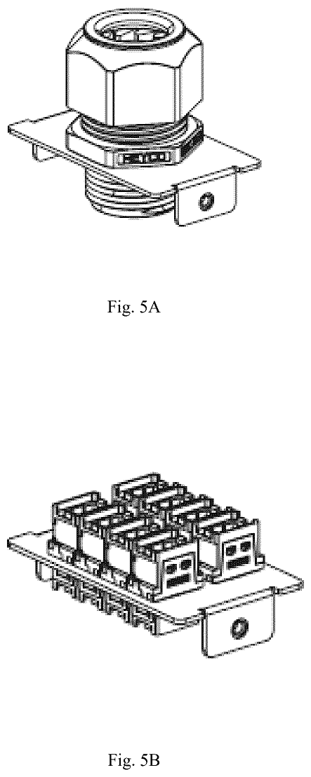

In one embodiment, the enclosure 10 may have a number of multi-fiber trunk cables 70 or backbone connections entering at the top or bottom of the enclosure which are distributed to a number of duplex fiber connectors exiting at different heights on the front of the application-specified adapter-aligned enclosure (FIG. 4). The multi-fiber trunk and fiber backbone cables 70 can be connected to the application-specified adapter-aligned enclosure with standard fiber connectors or fusion spliced to ribbon style fiber pigtails on site through a grommet (FIG. 5A). Standard multi-fiber connectors and adapters on the application-specified adapter-aligned enclosure may include but are not limited to MPO/MTP, SN-MT, and MMC type connectors (FIG. 5B).

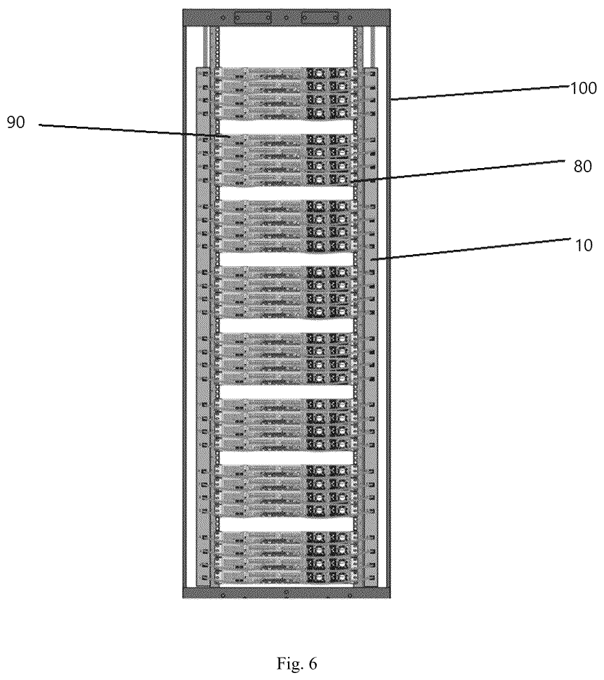

End devices 90 mounted in an equipment cabinet's 100 RU space can be connected to the application-specified adapter-aligned enclosure 10 with fiber patch cables 80 using standard duplex fiber connectors. The enclosure's duplex fiber connections can be aligned with the cabinet's RU numbering, allowing for all devices to use the same length duplex fiber patch cable (FIG. 6). Standard duplex fiber connectors and adapters located along the height of the front of the application-specified adapter-aligned enclosure may include but are not limited to SC, ST, LC, CS, SN, and MDC type.

Duplex fiber connections on the front of the application-specified adapter-aligned enclosure can be arranged in several configurations and groupings. One non-limiting example of the application-specified adapter-aligned enclosure may utilize a single LC duplex fiber connector oriented horizontally for each RU space. Another non-limiting example of the application-specified adapter-aligned enclosure may utilize two or more LC duplex fiber connectors oriented vertically for each RU space.

Multi-fiber connectors can be used in place of duplex fiber connectors along the face of the application-specified adapter-aligned enclosure when more fiber connectivity is needed for high-bandwidth connectivity. In one non-limiting example a high fiber count trunk fiber can be spliced to the top or bottom of the application-specified adapter-aligned enclosure and is broken out or “split” into multiple multi-fiber connectors located on the front of the application-specified adapter-aligned enclosure and aligned with the network cabinet's RU numbering.

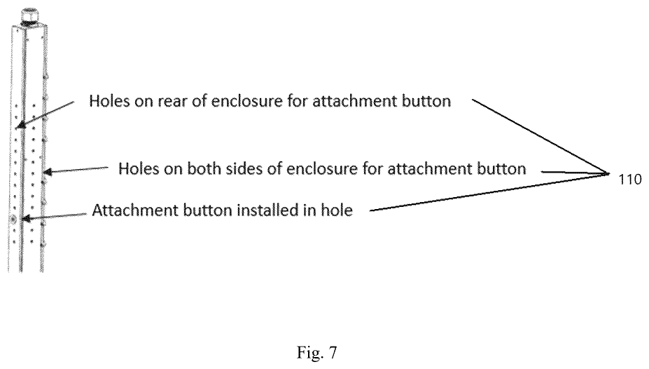

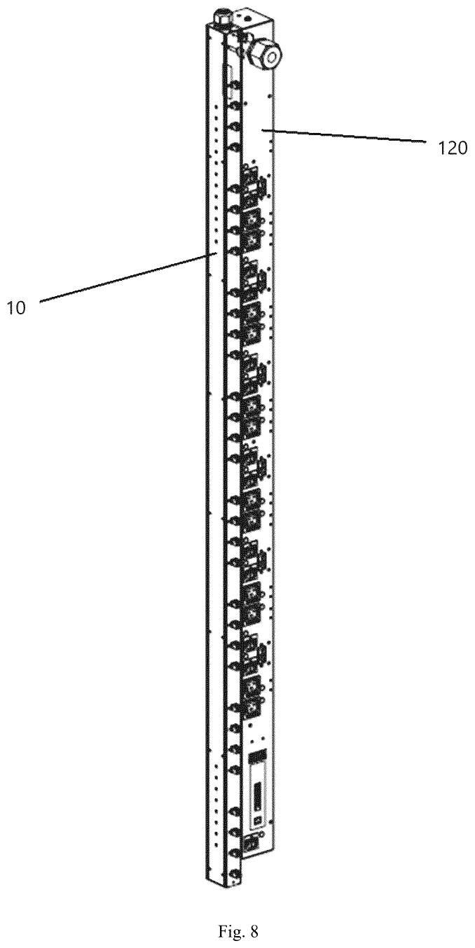

The enclosure can attach to other structures using attachment devices 110 on the enclosure (FIG. 7). This allows the enclosure to be attached to a PDU 120 (FIG. 8), cable management finger holes, or other connection devices or support brackets.

In one embodiment, the enclosure can include bar QR codes or bar codes on the bottom, top or side of the optical port adapters, enabling easy mapping and documentation of the interconnection using manual methods, mobile phone or scanner, or automatic detections, e.g., cameras in the rack doors.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1. An application-specified adapter-aligned enclosure to be placed in a server cabinet comprising a hole in at least one of a top or bottom of the enclosure and a plurality of fiber optic connectors distributed on a front face of the enclosure wherein the connectors are arranged in a plurality of groups which are vertically arranged in a specific manner related to at least one of a rack unit of a cabinet or an equipment port interval.

2. The application-specified adapter-aligned enclosure of claim 1, wherein the enclosure is attached to at least one of a rail, cable management finger slot, or a PDU in the server cabinet.

3. The application-specified adapter-aligned enclosure of claim 1, wherein the enclosure spans nearly the height of the server cabinet.

4. The application-specified adapter-aligned enclosure of claim 1, further comprising multi-fiber trunk cables or backbone connections entering the hole in the at least one of the top or bottom of the enclosure being distributed to the plurality of fiber optic connectors.

5. The application-specified adapter-aligned enclosure of claim 1, wherein the vertically arranged groups of fiber topic connectors include at least one vertically oriented LC duplex fiber connector.

6. The application-specified adapter-aligned enclosure of claim 1, wherein the vertically arranged groups of fiber topic connectors include at least one horizontally oriented LC duplex fiber connector.

7. The application-specified adapter-aligned enclosure of claim 1, further comprising attachment devices.

8. The application-specified adapter-aligned enclosure of claim 1, further comprising at least one of a QR code or bar code to be used for mapping and documenting interconnections.
